(19) United States
(12) Patent Application Publication
(10) Pub. No.: US 2025/0120055 A1
(43) Pub. Date: Apr. 10, 2025

(54) RADIOFREQUENCY SIGNALS ABSORBED BY CARBON FIBER AND/OR GRAPHITE, AND THE USE THEREOF

(71) Applicant: Fernando Ramirez Tapia, Vallejo, CA (US)

(72) Inventor: Fernando Ramirez Tapia, Vallejo, CA (US)

(21) Appl. No.: 18/821,154

(22) Filed: Aug. 30, 2024

Related U.S. Application Data
(60) Provisional application No. 63/589,172, filed on Oct. 10, 2023.

(51) Int. Cl. H05K 9/00

(52) U.S. Cl. CPC H05K 9/009

(57) ABSTRACT

The use of carbon-fiber and/or graphite based material for absorbing radiofrequency interfering signals to protect equipment from PIM.

### CROSS-REFERENCE TO RELATED APPLICATIONS

This application claims priority from a U.S. Provisional Patent Appl. No. 63/589,172, filed on Oct. 10, 2023, which is incorporated herein by reference in its entirety.

### FIELD OF INVENTION

The present invention relates to the use of carbon fiber-based materials and/or graphite-based materials, and more particularly, the present invention relates to the use of carbon fiber-based materials and/or graphite-based materials in devices for absorbing interfering RF signals preventing active and passive intermodulation.

### BACKGROUND

Electromagnetic Interference (EMI), caused by external sources, has been a major problem in electronics and networking. The electromagnetic interference travels along the conductors in power lines and signal lines. The electromagnetic waves propagating through space can affect Wireless communication and electronic devices. There could be a variety of sources of interference, such as lightning, electronic devices, electrical circuits, electrical appliances, power supplies, and the like. Electromagnetic interferences can cause the degrading of the performance of a device receiving the electromagnetic interferences. Similarly, electromagnetic interferences can also cause data corruption and device failures.

EMI shielding is used in conductors and devices to block the entry and exit of electromagnetic interferences. However, the efficacy of shielding varies significantly and is of limited applicability.

An industrial need is therefore appreciated for overcoming the limitations of EMI shielding.

The term interference(s) hereinafter refers to RF signal interference(s) and includes active intermodulation and passive intermodulation. Also, any reference to “carbon fiber” based materials include “graphite” based materials unless otherwise stated.

### SUMMARY OF THE INVENTION

The following presents a simplified summary of one or more embodiments of the present invention to provide a basic understanding of such embodiments. This summary is not an extensive overview of all contemplated embodiments and is intended to neither identify key or critical elements of all embodiments nor delineate the scope of any or all embodiments. Its sole purpose is to present some concepts of one or more embodiments in a simplified form as a prelude to the more detailed description that is presented later.

The principal object of the present invention is therefore directed to a method for absorbing radiofrequency signals protecting electronic devices, circuits, and the like.

Another object of the present invention is that the method can be applied to a variety of devices, articles, composites, and the like.

Still another object of the present invention is to prevent any active or passive intermodulation in networking or communication devices.

In one aspect, disclosed is a method for absorbing interfering radiofrequency signals to reduce or eliminate RF interferences, active intermodulation, and passive intermodulation using carbon fiber-based materials and/or graphite-based materials.

In one aspect, disclosed is a method of protecting electronic devices from RF signal interferences, the method comprises incorporating carbon fiber-based materials and/or graphite-based materials in the manufacture of devices as a part of composition, outer layer, or outer covering, wherein the carbon fiber-based materials and/or graphite-based materials can absorb the interfering RF signals to prevent any interferences that may affect the performance and/or life of the device.

In one aspect, the device can be a conductor, and the carbon fiber-based materials and/or graphite-based materials can be incorporated into the insulating covering of the conductor.

In one aspect, the device can be networking equipment, and the carbon fiber-based materials and/or graphite-based materials can be used in the manufacture of the networking equipment, as a shield, covering, barrier, and the like. The equipment can be an electronic circuit.

In one aspect, disclosed is a device comprising a protective layer, the protective layer comprising carbon fiber-based materials and/or graphite-based materials, wherein the carbon fiber-based materials and/or graphite-based materials are configured to absorb interfering RF signals.

In one aspect, disclosed is a device comprising a protective barrier, wherein the protective barrier comprises carbon fiber-based materials and/or graphite-based materials for absorbing interfering RF signals.

### BRIEF DESCRIPTION OF DRAWINGS

The accompanying figures, which are incorporated herein, form part of the specification and illustrate embodiments of the present invention. Together with the description, the figures further explain the principles of the present invention and enable a person skilled in the relevant arts to make and use the invention.

FIG. 1 is a schematic diagram illustrating the protection of equipment from electromagnetic interference by a barrier made of carbon fiber-based materials and/or graphite-based materials, according to an exemplary embodiment of the present invention.

FIG. 2 shows a conductor with an insulative layer made from carbon fiber-based materials and/or graphite-based materials, according to an exemplary embodiment of the present invention.

### DETAILED DESCRIPTION

Subject matter will now be described more fully hereinafter with reference to the accompanying drawings, which form a part hereof, and which show, by way of illustration, specific exemplary embodiments. Subject matter may, however, be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended. Among other things, for example, the subject matter may be embodied as methods, devices, components, or systems. The following detailed description is, therefore, not intended to be taken in a limiting sense.

The word “exemplary” is used herein to mean “serving as an example, instance, or illustration.” Any embodiment described herein as “exemplary” is not necessarily to be construed as preferred or advantageous over other embodiments. Likewise, the term “embodiments of the present invention” does not require that all embodiments of the invention include the discussed feature, advantage, or mode of operation.

The terminology used herein is to describe particular embodiments only and is not intended to be limiting to embodiments of the invention. As used herein, the singular forms “a”, “an” and “the” are intended to include the plural forms as well, unless the context clearly indicates otherwise. It will be further understood that the terms “comprise”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The following detailed description includes the best currently contemplated mode or modes of carrying out exemplary embodiments of the invention. The description is not to be taken in a limiting sense but is made merely to illustrate the general principles of the invention since the scope of the invention will be best defined by the allowed claims of any resulting patent.

Disclosed is a method for absorbing interfering RF signals to reduce, block, and/or eliminate RF interferences. The disclosed method can be applied to conductors, electronic circuits, electronic devices, networking equipment, and the like, and such things that can be affected by RF interferences are referred to herein as a device or an equipment. The device includes any presentation, such as antenna covers to reduce back lobe PIM, PIM absorbing tape, voltage protection devices, anything in proximity to antennas, etc. The disclosed method uses carbon fiber-based materials and/or graphite-based materials for absorbing the interfering RF signals protecting the device from interfering RF signals preventing any passive intermodulation.

In certain implementations, carbon fiber-based materials and/or graphite-based materials can be used in protective and/or insulation coverings for the equipment. carbon fiber-based materials and/or graphite-based materials can also be used in any supporting structure of the equipment. carbon fiber-based materials and/or graphite-based materials can absorb the interfering RF signals resulting in reduction, blockage, and/or elimination of RF interferences.

In one implementation, the equipment can include cable support, antennas, voltage-protecting devices, mounting systems, etc. The carbon fiber-based materials and/or graphite-based materials, used as RF absorbing material, can be used in near radio antenna systems and in mobile networks for improving the network quality and coverage. Carbon fiber-based materials and/or graphite-based materials can be used in a variety of ways as an RF absorbent on mobile networks. Similarly, carbon fiber-based materials and/or graphite-based materials can be used in a variety of ways as an RF absorbent in different equipment. The use of carbon fiber-based materials and/or graphite-based materials in the manufacture of devices, covering, or shield can provide protection against passive intermodulation in networking and communications.

In one implementation, an antenna system was set up, using an antenna, coax cable, and a PIM (Passive Intermodulation) device to see any changes or improvements. An external PIM source was placed in front and back of the antenna, creating some external PIM, also noticeable on the PIM equipment. Then a carbon fiber sheet and a graphite tape were placed separately, in which both materials mitigated the external PIM source, having baseline readings again as if there was no PIM source in front and/or back of the antenna. Thus, it was observed that the use of carbon fiber-based materials and/or graphite-based materials and composites could effectively eliminate external electromagnetic interferences.

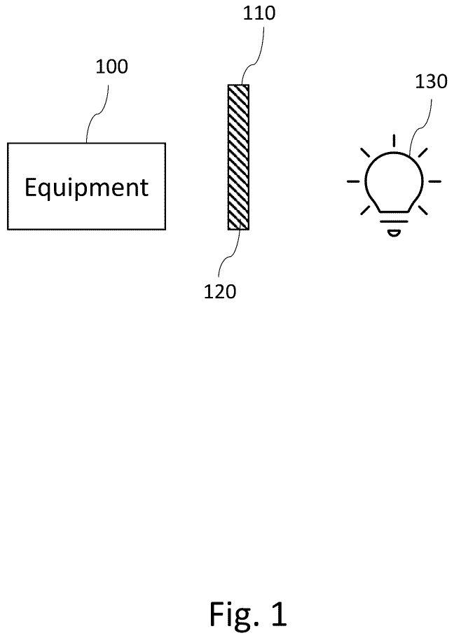

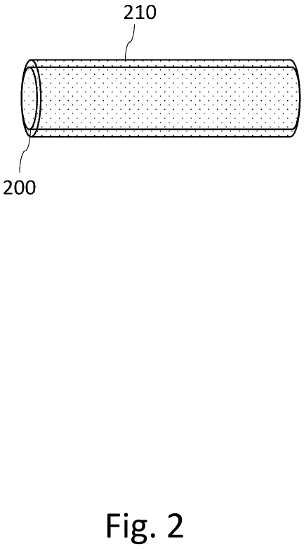

Referring to FIG. 1 which is a schematic diagram illustrating equipment 100, a barrier 110 made from carbon fibers 120 positioned between the equipment and a source of electromagnetic interferences 130 for shielding the equipment from the RF electromagnetic interferences. FIG. 2 shows a conductor 200 that can be made from copper and the like conducting material. The conductor is covered by a protective and insulative sheath 210. The sheath includes carbon fibers for absorbing the RF electromagnetic fields to prevent the same from entering the conductor.

The device can also be an RF barrier tape that can be self-adhesive and includes a release liner to cover the adhesive layer. The RF barrier tape is made from carbon fiber-based materials and/or graphite-based materials. The RF barrier tape can be multilayers, wherein one or more layers can be made from carbon fiber-based materials and/or graphite-based materials.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiment, method, and examples, but by all embodiments and methods within the scope and spirit of the invention as claimed.

What is claimed is:

1. A method of protecting a device from radiofrequency signal (RF) interferences and passive intermodulation effects (PIM), the method comprises:
configuring an article made of carbon-fiber and/or graphite based material in and/or around the device, wherein carbon-fiber and/or graphite based material absorbs interfering RF signals to prevent PIM or RF interferences.

2. The method of claim 1, wherein the device is a conductor, and the article is an insulating covering of the conductor.

3. The method of claim 1, wherein the device is networking equipment, and the article is a barrier.

4. The method of claim 1, wherein the device is an electronic circuit, and the article is a barrier.

5. A device comprising a protective layer, the protective layer comprising carbon-fiber and/or graphite based material, wherein the carbon-fiber and/or graphite based material is configured to absorb interfering radiofrequency signals and prevent PIM.

6. A device comprises a protective barrier, wherein the protective barrier comprises carbon-fiber and/or graphite based material for absorbing interfering radiofrequency signals and preventing PIM.
